(19) United States
(12) Patent Application Publication
(10) Pub. No.: US 2022/0020803 A1
(43) Pub. Date: Jan. 20, 2022

(54) SEMICONDUCTOR DEVICE AND METHOD FOR FABRICATING THE SAME

(71) Applicant: SAMSUNG ELECTRONICS CO., LTD., SUWON-SI (KR)

(72) Inventors: Han Seok KIM, Seoul (KR); Byung Jun PARK, Yongin-si (KR); Byoung Ho KIM, Suwon-si (KR); Hee Geun JEONG, Suwon-si (KR)

(21) Appl. No.: 17/190,796

(22) Filed: Mar. 3, 2021

(30) Foreign Application Priority Data
Jul. 15, 2020 (KR) 10-2020-0087212

(51) Int. Cl. H01L 27/146

(52) U.S. Cl. CPC H01L 27/14636; H01L 27/1463

(57) ABSTRACT

A semiconductor device including: a first substrate including a first surface and a second surface; a first inter-wiring insulating film on the first substrate; a first wiring in the first inter-wiring insulating film; a landing via in the first inter-wiring insulating film, and spaced apart from the first wiring; a second substrate including a third surface and a fourth surface; a second inter-wiring insulating film on the second substrate; a second wiring in the second inter-wiring insulating film; and a through via structure penetrating the second substrate and the second inter-wiring insulating film, and electrically connecting the second wiring to the landing via, wherein with respect to the second surface of the first substrate, a top surface of the landing via is higher than a bottom surface of the first wiring, and a bottom surface of the landing via is lower than the bottom surface of the first wiring.

### CROSS-REFERENCE TO RELATED APPLICATION

This application claims priority under 35 U.S.C. § 119 to Korean Patent Application No. 10-2020-0087212 filed on Jul. 15, 2020 in the Korean Intellectual Property Office, the disclosure of which is incorporated by reference herein in its entirety.

### TECHNICAL FIELD

The present inventive concept relates to a semiconductor device and a method for fabricating the same. More particularly, the present inventive concept relates to a semiconductor device including a through via structure and a method for fabricating the same.

### DISCUSSION OF THE RELATED ART

As semiconductor devices have become more integrated and have increased in capacity, techniques for stacking individual wafers have been under development. For example, a through silicon via (TSV) technique is a technique for connecting individual wafers (e.g., a lower substrate and an upper substrate) by forming a trench penetrating a silicon substrate and forming a through via structure in the trench.

### SUMMARY

According to an exemplary embodiment of the present inventive concept, a semiconductor device including: a first substrate including a first surface and a second surface opposite to each other; a first inter-wiring insulating film stacked on the first substrate; a first wiring in the first inter-wiring insulating film; a landing via in the first inter-wiring insulating film, wherein the landing via is spaced apart from the first wiring; a second substrate overlapping the first substrate and including a third surface and a fourth surface opposite to the third surface; a second inter-wiring insulating film stacked on the second substrate; a second wiring in the second inter-wiring insulating film; and a through via structure configured to penetrate the second substrate and the second inter-wiring insulating film, and to electrically connect the second wiring to the landing via, wherein with respect to the second surface of the first substrate, a top surface of the landing via is higher than a bottom surface of the first wiring, and a bottom surface of the landing via is lower than the bottom surface of the first wiring.

According to an exemplary embodiment of the present inventive concept, a semiconductor device including: a first substrate including a first surface and a second surface opposite to each other; a lower insulating film and an upper insulating film on the first substrate;

a lower wiring in the lower insulating film, wherein the lower wiring is exposed at a top surface of the lower insulating film; a first wiring in the upper insulating film; a connection via in the upper insulating film, wherein the connection via extends from the first wiring to connect the first wiring to the lower wiring; a landing via in the upper insulating film, wherein the landing via is spaced apart from the first wiring; a second substrate overlapping the first substrate and including a third surface and a fourth surface opposite to the third surface; a second inter-wiring insulating film stacked on the second substrate; and a through via structure configured to penetrate the second substrate and the second inter-wiring insulating film, and connected to the landing via, wherein a top surface of the landing via is further spaced apart from the lower insulating film than a bottom surface of the first wiring, and wherein a bottom surface of the landing via is coplanar with a bottom surface of the connection via.

According to an exemplary embodiment of the present inventive concept, a semiconductor device includes: a sensor array region; a connection region around the sensor array region; a first substrate including a first surface and a second surface opposite to each other; a photoelectric conversion layer in the first substrate of the sensor array region; a first insulating structure stacked on the first substrate; a first wiring in the first insulating structure of the connection region; a landing via in the first insulating structure of the connection region, wherein the landing via is spaced apart from the first wiring; a second substrate overlapping the first substrate and including a third surface and a fourth surface opposite to the third surface; a second insulating structure on the second substrate, wherein the second insulating structure is bonded to the first insulating structure; and a through via structure configured to penetrate the second substrate and the second insulating structure, and connected to the landing via, wherein with respect to the second surface of the first substrate, a top surface of the landing via is higher than a bottom surface of the first wiring, and a bottom surface of the landing via is lower than the bottom surface of the first wiring.

### BRIEF DESCRIPTION OF THE DRAWINGS

The above and other features of the present inventive concept will become more apparent by describing in detail exemplary embodiments thereof, with reference to the accompanying drawings, in which:

FIG. 1 is a diagram illustrating a semiconductor device according to an exemplary embodiment of the present inventive concept.

FIG. 2 is a schematic cross-sectional view taken along line A-A of FIG. 1.

FIG. 3 is an enlarged view illustrating area R of FIG. 2.

FIG. 4 is a schematic cross-sectional view illustrating a semiconductor device according to an exemplary embodiment of the present inventive concept.

FIG. 5 is a schematic cross-sectional view illustrating a semiconductor device according to an exemplary embodiment of the present inventive concept.

FIG. 6 is a layout diagram illustrating a semiconductor device according to an exemplary embodiment of the present inventive concept.

FIG. 7 is a layout diagram illustrating a semiconductor device according to an exemplary embodiment of the present inventive concept.

FIG. 8 is a schematic cross-sectional view taken along line B-B of FIG. 7.

FIG. 9 is a layout diagram illustrating a semiconductor device according to an exemplary embodiment of the present inventive concept.

FIG. 10 is a schematic cross-sectional view taken along line C-C of FIG. 9.

FIG. 11A is a layout diagram illustrating a semiconductor device according to an exemplary embodiment of the present inventive concept.

FIG. 11B is a layout diagram illustrating a semiconductor device according to an exemplary embodiment of the present inventive concept.

FIG. 12 is a layout diagram illustrating an image sensor according to an exemplary embodiment of the present inventive concept.

FIG. 13 is a schematic cross-sectional view illustrating the image sensor of FIG. 12.

FIG. 14 is a schematic cross-sectional view illustrating an image sensor according to an exemplary embodiment of the present inventive concept.

FIGS. 15, 16, 17, 18, 19, 20, 21 and 22 are views illustrating steps of a method for fabricating a semiconductor device according to an exemplary embodiment of the present inventive concept.

### DETAILED DESCRIPTION OF THE EMBODIMENTS

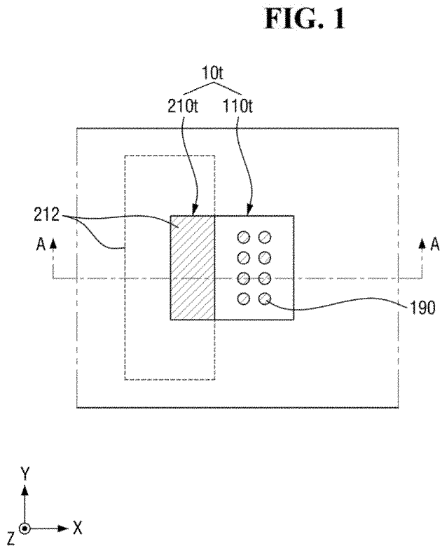

Hereinafter, a semiconductor device according to an exemplary embodiment of the present inventive concept will be described with reference to FIGS. 1 to 11B.

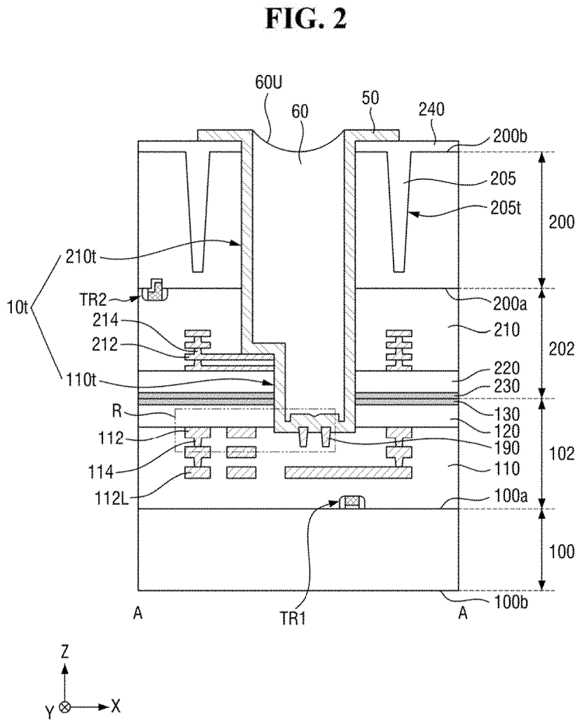

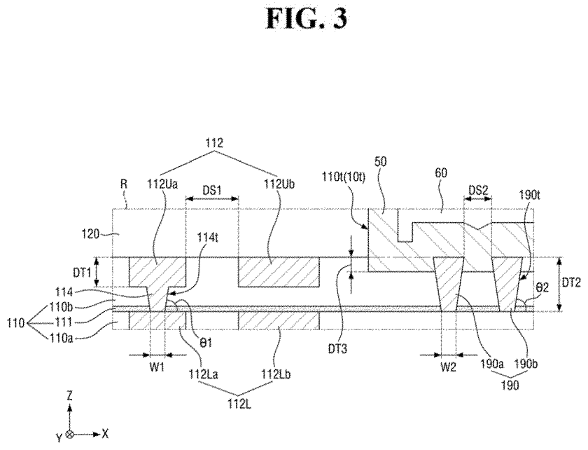

FIG. 1 is a layout diagram illustrating a semiconductor device according to an exemplary embodiment of the present inventive concept. FIG. 2 is a schematic cross-sectional view taken along line A-A of FIG. 1. FIG. 3 is an enlarged view illustrating area R of FIG. 2.

Referring to FIGS. 1 to 3, a semiconductor device according to an exemplary embodiment of the present inventive concept includes a first substrate 100, a first insulating structure 102, a first wiring 112, a first connection via 114, a first landing via 190, a second substrate 200, a second insulating structure 202, a second wiring 212, a second connection via 214, and a first through via structure 50.

The first substrate 100 may be a semiconductor substrate. For example, the first substrate 100 may be a bulk silicon or silicon-on-insulator (SOI) substrate. For example, the first substrate 100 may be a silicon substrate, or may include other materials such as silicon germanium, indium antimonide, lead tellurium compound, indium arsenide, indium phosphide, gallium arsenide, or gallium antimonide. As an additional example, the first substrate 100 may have an epitaxial layer formed on a base substrate.

The first substrate 100 may include a first surface 100b and a second surface 100a opposite to each other. In an exemplary embodiment of the present inventive concept, the first surface 100b may be a back side of the first substrate 100, and the second surface 100a may be a front side of the first substrate 100.

The first insulating structure 102 may be stacked on the second surface 100a of the first substrate 100. In an exemplary embodiment of the present inventive concept, the first insulating structure 102 may be formed of multiple films. For example, the first insulating structure 102 may include a first inter-wiring insulating film 110, a first interlayer insulating film 120, and a first adhesive film 130, which are sequentially stacked on the second surface 100a of the first substrate 100.

A plurality of wirings 112 and 112L may be formed in the first inter-wiring insulating film 110. The plurality of wirings 112 and 112L may be formed into multiple layers to form an electrical path. For example, the plurality of wirings 112 and 112L may each extend on a plane (e.g., a plane including a first direction X and a second direction Y) parallel to the second surface 100a of the first substrate 100 to form the electrical path. The arrangements and the number of layers of the wirings 112 and 112L disposed in the first inter-wiring insulating film 110 shown in FIG. 2 are merely examples, and the present inventive concept is not limited thereto.

The first interlayer insulating film 120 may be formed on the first inter-wiring insulating film 110. For example, the first interlayer insulating film 120 may cover the top surface of the first inter-wiring insulating film 110.

Each of the first inter-wiring insulating film 110 and the first interlayer insulating film 120 may include, for example, at least one of silicon oxide, silicon nitride, silicon oxynitride, or a low-k material having a lower dielectric constant than, for example, silicon oxide, but the present inventive concept is not limited thereto.

The first adhesive film 130 may be formed on the first interlayer insulating film 120.

For example, the first adhesive film 130 may cover the top surface of the first interlayer insulating film 120. The first adhesive film 130 may be bonded to a second adhesive film 230. The first adhesive film 130 may include, for example, silicon carbonitride (SiCN), but the present inventive concept is not limited thereto.

In an exemplary embodiment of the present inventive concept, the first inter-wiring insulating film 110 may be formed of multiple films. For example, as illustrated in FIG. 3, the first inter-wiring insulating film 110 may include a lower insulating film 110a and an upper insulating film 110b, which are sequentially stacked on the second surface 100a of the first substrate 100. The plurality of wirings 112 and 112L may be formed into multiple layers in the first inter-wiring insulating film 110 formed of multiple films. For example, the plurality of wirings 112 and 112L may include the first wiring 112 and a lower wiring 112L. The first wiring 112 may be formed in the upper insulating film 110b, and the lower wiring 112L may be formed in the lower insulating film 110a. The first wiring 112 may be disposed on the lower wiring 112L. For example, the lower wiring 112L may be disposed below the first wiring 112.

In an exemplary embodiment of the present inventive concept, the top surface of the first wiring 112 may be exposed at the top surface of the upper insulating film 110b, and the top surface of the lower wiring 112L may be exposed at the top surface of the lower insulating film 110a.

In an exemplary embodiment of the present inventive concept, an etch stop film 111 may be interposed between the lower insulating film 110a and the upper insulating film 110b. For example, the etch stop film 111 may be formed to cover the top surface of the lower insulating film 110a. The etch stop film 111 may include a material having an etching selectivity different from that of the lower insulating film 110a and the upper insulating film 110b. For example, the lower insulating film 110a and the upper insulating film 110b may include silicon oxide, and the etch stop film 111 may include silicon carbonitride, but the present inventive concept is not limited thereto.

In an exemplary embodiment of the present inventive concept, the first wiring 112 may be an uppermost wiring of the plurality of wirings 112 and 112L formed in the first inter-wiring insulating film 110. For example, the top surface of the first wiring 112 may be exposed at the top surface of the first inter-wiring insulating film 110. However, the present inventive concept is not limited thereto, and the first wiring 112 may not be the uppermost wiring of the plurality of wirings 112 and 112L formed in the first inter-wiring insulating film 110.

The first connection via 114 may be formed in the first insulating structure 102. For example, the first connection via 114 may be formed in the first inter-wiring insulating film 110. The first connection via 114 may interconnect the plurality of wirings 112 and 112L that are formed into multiple layers in the first inter-wiring insulating film 110. For example, as shown in FIG. 3, the first connection via 114 may extend from a first upper wiring 112Ua to connect the first upper wiring 112Ua to a first lower wiring 112La. For example, the first connection via 114 may extend from a bottom surface of the first upper wiring 112Ua.

The first connection via 114 may be formed by a via process. For example, a first via trench 114t exposing the top surface of the first lower wiring 112La may be formed in the upper insulating film 110b. The first connection via 114 may be formed to fill the first via trench 114t.

In an exemplary embodiment of the present inventive concept, the first connection via 114 may have, for example, a pillar shape or a rectangular shape. For example, the first connection via 114 may have a cylindrical shape extending in a third direction Z, but the present inventive concept is not limited thereto.

In an exemplary embodiment of the present inventive concept, a width W1 of the first connection via 114 may decrease as it approaches the second surface 100a of the first substrate 100. For example, this may be due to the fact that an etching process for forming the first connection via 114 is performed toward the second surface 100a of the first substrate 100.

In an exemplary embodiment of the present inventive concept, the first connection via 114 may penetrate the etch stop film 111 to contact the top surface of the lower wiring 112L.

The plurality of wirings 112 and 112L and the first connection via 114 may include a conductive material. The plurality of wirings 112 and 112L and the first connection via 114 may each include, for example, at least one of copper (Cu), tungsten (W), tungsten nitride (WN), tantalum (Ta), titanium (Ti), tantalum nitride (TaN), titanium nitride (TiN), cobalt (Co), manganese (Mn), aluminum (Al), or aluminum nitride (AlN), but the present inventive concept not limited thereto. In an exemplary embodiment of the present inventive concept, the plurality of wirings 112 and 112L and the first connection via 114 may be formed of the same conductive material.

In an exemplary embodiment of the present inventive concept, the plurality of wirings 112 and 112L and the first connection via 114 may be electrically connected to a first electronic element TR1 formed on the first substrate 100. For example, the first electronic element TR1 may be formed on the second surface 100a of the first substrate 100. The first inter-wiring insulating film 110 may cover the first electronic element TR1. The first electronic element TR1 may be, for example, a transistor, but the present inventive concept is not limited thereto.

The first landing via 190 may be formed in the first insulating structure 102. The first landing via 190 may be electrically connected to the first through via structure 50. Further, the first landing via 190 may be electrically connected to some of the plurality of wirings 112 and 112L. Accordingly, the first landing via 190 may electrically connect the first through via structure 50 to the plurality of wirings 112 and 112L.

The first landing via 190 may be disposed at substantially the same level as the first wiring 112. For example, as illustrated in FIG. 3, both the first wiring 112 and the first landing via 190 may be formed in the upper insulating film 110b.

With respect to the second surface 100a of the first substrate 100, the top surface of the first landing via 190 may be formed higher than the bottom surface of the first wiring 112. For example, the top surface of the first landing via 190 may be further spaced apart from the top surface of the lower insulating film 110a than the bottom surface of the first wiring 112.

In an exemplary embodiment of the present inventive concept, the top surface of the first landing via 190 may be coplanar with the top surface of the first wiring 112. For example, both the top surface of the first landing via 190 and the top surface of the first wiring 112 may be coplanar with the top surface of the upper insulating film 110b (or, e.g., the top surface of the first inter-wiring insulating film 110). However, the present inventive concept is not limited thereto, and for example, the top surface of the first landing via 190 may be formed lower than the top surface of the first wiring 112 and/or the top surface of the upper insulating film 110b.

With respect to the second surface 100a of the first substrate 100, the bottom surface of the first landing via 190 may be formed lower than the bottom surface of the first wiring 112. For example, with respect to the top surface of the upper insulating film 110b, a depth DT2 at which the bottom surface of the first landing via 190 is formed may be greater than a depth DT1 at which the bottom surface of the first wiring 112 is formed in the upper insulating film 110b.

In an exemplary embodiment of the present inventive concept, the depth DT1 at which the bottom surface of the first wiring 112 is formed may be about 1500 < to about 2000 Å. In an exemplary embodiment of the present inventive concept, the depth DT2 at which the bottom surface of the first landing via 190 is formed may be about 3000 Å to about 4000 Å.

In an exemplary embodiment of the present inventive concept, the bottom surface of the first landing via 190 may be coplanar with the bottom surface of the first connection via 114.

For example, both the bottom surface of the first landing via 190 and the bottom surface of the first connection via 114 may be coplanar with the top surface of the lower insulating film 110a.

In an exemplary embodiment of the present inventive concept, the first landing via 190 may be formed by a via process. For example, a second via trench 190t exposing the top surface of the lower insulating film 110a may be formed in the upper insulating film 110b. The first landing via 190 may be formed to fill the second via trench 190t.

In an exemplary embodiment of the present inventive concept, the first landing via 190 may have a pillar shape or rectangular shape. For example, the first landing via 190 may have a cylindrical shape extending in a third direction Z, but the present inventive concept is not limited thereto.

In an exemplary embodiment of the present inventive concept, a width W2 of the first landing via 190 may decrease as it approaches the second surface 100a of the first substrate 100. For example, this may be due to the fact that an etching process for forming the first landing via 190 is performed toward the second surface 100a of the first substrate 100.

In an exemplary embodiment of the present inventive concept, a width W2 of the first landing via 190 may be the same as a width W1 of the first connection via 114. For example, this may be due to the fact that the first landing via 190 is formed by the same via process as the first connection via 114. The term “same” as used herein not only means being completely identical but also includes about a minute or less difference that may occur due to a process margin and the like.

In an exemplary embodiment of the present inventive concept, the side surface of the first landing via 190 may have the same slope as the side surface of the first connection via 114. For example, an acute angle θ2 formed by the top surface of the lower insulating film 110a and the side surface of the first landing via 190 may be the same as an acute angle 01 formed by the top surface of the lower wiring 112L and the side surface of the first connection via 114.

In an exemplary embodiment of the present inventive concept, the first landing via 190 may be formed with a finer pitch than the wirings 112 and 112L in the first insulating structure 102. For example, the first landing via 190 may include a first sub-via 190a and a second sub-via 190b adjacent to each other. The first wiring 112 may include the first upper wiring 112Ua and a second upper wiring 112Ub adjacent to each other (or, e.g., the lower wiring 112L may include the first lower wiring 112La and a second lower wiring 112Lb adjacent to each other). In this case, a separation distance DS2 between the first sub-via 190a and the second sub-via 190b may be smaller than a separation distance DS1 between the first upper wiring 112Ua and the second upper wiring 112Ub (or a separation distance between the first lower wiring 112La and the second lower wiring 112Lb).

In an exemplary embodiment of the present inventive concept, the first landing via 190 may penetrate the etch stop film 111 to contact the top surface of the lower insulating film 110a.

The first landing via 190 may include a conductive material. The first landing via 190 may include, for example, at least one of copper (Cu), tungsten (W), tungsten nitride (WN), tantalum (Ta), titanium (Ti), tantalum nitride (TaN), titanium nitride (TiN), cobalt (Co), manganese (Mn), aluminum (Al), or aluminum nitride (AlN), but the present inventive concept is not limited thereto. In an exemplary embodiment of the present inventive concept, the first landing via 190 may be formed of the same conductive material as the first wiring 112 and/or the first connection via 114.

The second substrate 200 may be a semiconductor substrate. For example, the second substrate 200 may be a bulk silicon or silicon-on-insulator (SOI) substrate. The second substrate 200 may be a silicon substrate, or may include other materials such as silicon germanium, indium antimonide, lead tellurium compound, indium arsenide, indium phosphide, gallium arsenide, or gallium antimonide. For example, the second substrate 200 may have an epitaxial layer formed on a base substrate.

The second substrate 200 may include a third surface 200a and a fourth surface 200b opposite to each other. In an exemplary embodiment of the present inventive concept, the third surface 200a may be a front side of the second substrate 200, and the fourth surface 200b may be a back side of the second substrate 200. However, the present inventive concept is not limited thereto.

The second insulating structure 202 may be stacked on the third surface 200a of the second substrate 200. In an exemplary embodiment of the present inventive concept, the second insulating structure 202 may be formed of multiple films. For example, the second insulating structure 202 may include a second inter-wiring insulating film 210, a second interlayer insulating film 220, and a second adhesive film 230 that are sequentially stacked on the third surface 200a of the second substrate 200.

A plurality of second wirings 212 may be formed in the second inter-wiring insulating film 210. The plurality of second wirings 212 may be formed into multiple layers to form an electrical path. For example, the plurality of second wirings 212 may each extend on a plane (e.g., a plane including a first direction X and a second direction Y) parallel to the third surface 200a of the second substrate 200 to form the electrical path. The arrangement and the number of layers of the second wirings 212 disposed in the second inter-wiring insulating film 210 shown in FIG. 2 are merely an examples, and the present inventive concept is not limited thereto.

The second interlayer insulating film 220 may be formed on the second inter-wiring insulating film 210. For example, the second interlayer insulating film 220 may cover the bottom surface of the second inter-wiring insulating film 210.

Each of the second inter-wiring insulating film 210 and the second interlayer insulating film 220 may include, for example, at least one of silicon oxide, silicon nitride, silicon oxynitride, or a low-k material having a lower dielectric constant than that of silicon oxide, but the present inventive concept not limited thereto.

The second adhesive film 230 may be formed on the second interlayer insulating film 220. For example, the second adhesive film 230 may cover the bottom surface of the second interlayer insulating film 220. The second adhesive film 230 may be bonded to the first adhesive film 130. For example, the bottom surface of the second adhesive film 230 may be bonded to the top surface of the first adhesive film 130. The second adhesive film 230 may include, for example, silicon carbonitride (SiCN), but the present inventive concept is not limited thereto.

The second connection via 214 may be formed in the second insulating structure 202. For example, the second connection via 214 may be formed in the second inter-wiring insulating film 210. The second connection via 214 may interconnect the second wirings 212 formed into multiple layers in the second inter-wiring insulating film 210. For example, the second connection via 214 may connect the second wirings 212 to each other.

In an exemplary embodiment of the present inventive concept, the second connection via 214 may have a pillar shape. For example, the second connection via 214 may have a cylindrical shape extending in a third direction Z, but the present inventive concept is not limited thereto.

In an exemplary embodiment of the present inventive concept, the width of the second connection via 214 may decrease as it approaches the third surface 200a of the second substrate 200. For example, this may be due to the fact that an etching process for forming the second connection via 214 is performed toward the third surface 200a of the second substrate 200.

In an exemplary embodiment of the present inventive concept, the second wirings 212 and the second connection via 214 may be electrically connected to a second electronic element TR2 formed on the second substrate 200. For example, the second electronic element TR2 may be formed on the third surface 200a of the second substrate 200. The second inter-wiring insulating film 210 may cover the second electronic element TR2. The second electronic element TR2 may be, for example, a transistor, but the present inventive concept is not limited thereto.

The first through via structure 50 may penetrate the second substrate 200 and the second insulating structure 202 to be connected to the first landing via 190. For example, a through via trench 10t exposing the first landing via 190 may be formed in the second substrate 200, the second insulating structure 202, and the first insulating structure 102. The first through via structure 50 may be formed in the through via trench 10t to be connected to the first landing via 190. In an exemplary embodiment of the present inventive concept, the first through via structure 50 may conformally extend along the profile of the through via trench 10t.

In an exemplary embodiment of the present inventive concept, the first through via structure 50 may connect the second wiring 212 to the first landing via 190. For example, the through via trench 10t may include a first sub-trench 110t and a second sub-trench 210t. The first sub-trench 110t exposes at least a part of the first landing via 190, and the second sub-trench 210t exposes at least a part of the second wiring 212. The first sub-trench 110t and the second sub-trench 210t may be connected to each other to form the through via trench 10t. The first through via structure 50 may extend along the profiles of the first and second sub-trenches 110t and 210t. Accordingly, the first through via structure 50 electrically connecting the second wiring 212 to the first landing via 190 may be formed.

In an exemplary embodiment of the present inventive concept, the through via trench 10t may penetrate the second substrate 200, the second insulating structure 202, the first adhesive film 130, and the first interlayer insulating film 120 to expose a part of the top surface of the first inter-wiring insulating film 110. For example, as illustrated in FIG. 3, the first sub-trench 110t may expose a part of the top surface of the upper insulating film 110b. Accordingly, the first landing via 190 exposed by the top surface of the upper insulating film 110b may be connected to the first through via structure 50.

FIG. 3 illustrates that the bottom surface of the first sub-trench 110t (or the through via trench 10t) is positioned between the top surface and the bottom surface of the first wiring 112, but the present inventive concept this is merely an example. As long as the first through via structure 50 is connected to the first landing via 190, the position of the bottom surface of the first sub-trench 110t is irrelevant. For example, the bottom surface of the first sub-trench 110t may be lower than the bottom surface of the first wiring 112 or lower than the bottom surface of the first landing via 190.

The first through via structure 50 may include a conductive material. For example, the first through via structure 50 may include at least one of titanium (Ti), titanium nitride (TiN), tantalum (Ta), tantalum nitride (TaN), tungsten (W), aluminum (Al), or copper (Cu), but the present inventive concept is not limited thereto.

In an exemplary embodiment of the present inventive concept, a surface insulating film 240 may be formed on the fourth surface 200b of the second substrate 200. The surface insulating film 240 may be formed to cover the fourth surface 200b of the second substrate 200. In an exemplary embodiment of the present inventive concept, a part of the first through via structure 50 may extend along the top surface of the surface insulating film 240.

The surface insulating film 240 may include, for example, at least one of silicon oxide, silicon nitride, silicon oxynitride, aluminum oxide, hafnium oxide, or a combination thereof, but the present inventive concept is not limited thereto.

In an exemplary embodiment of the present inventive concept, a filling insulating film 60 may be formed on the first through via structure 50. The filling insulating film 60 may be formed to fill at least a part of the through via trench 10t. The filling insulating film 60 may include, for example, at least one of silicon oxide, aluminum oxide, or tantalum oxide, but the present inventive concept is not limited thereto. In an exemplary embodiment of the present inventive concept, the filling insulating film 60 may include a low refractive index material having a refractive index lower than that of silicon (Si).

In an exemplary embodiment of the present inventive concept, a top surface 60U of the filling insulating film 60 may be concave. This may be due to a process (e.g., a deposition process and/or a planarization process) for forming the filling insulating film 60, but the present inventive concept is not limited thereto. For example, the top surface 60U of the filling insulating film 60 may be coplanar with a top surface of the first through via structure 50.

In an exemplary embodiment of the present inventive concept, an element isolation pattern 205 may be formed in the second substrate 200. The element isolation pattern 205 may be formed at the side of the first through via structure 50. For example, an element isolation trench 205t may be formed in the second substrate 200 at the side of the first through via structure 50. For example, the second substrate 200 may between the first through via structure 50 and the element isolation pattern 205. The element isolation pattern 205 may be formed to fill the element isolation trench 205t. For example, the element isolation pattern 205 may extend from the bottom surface of the surface insulating film 240. The element isolation pattern 205 may reduce a leakage current generated in the second substrate 200 due to the first through via structure 50.

In an exemplary embodiment of the present inventive concept, the width of the element isolation pattern 205 may decrease as it approaches the third surface 200a of the second substrate 200. For example, this may be due to the fact that an etching process for forming the element isolation trench 205t is performed from the fourth surface 200b of the second substrate 200.

In an exemplary embodiment of the present inventive concept, the element isolation pattern 205 may be spaced apart from the third surface 200a of the second substrate 200. For example, the element isolation trench 205t may not expose the top surface of the second inter-wiring insulating film 210.

The element isolation pattern 205 may include, for example, at least one of silicon oxide, silicon nitride, silicon oxynitride, aluminum oxide, tantalum oxide, or a combination thereof, but the present inventive concept is not limited thereto.

As semiconductor devices have become more integrated and have increased in capacity, techniques for stacking individual wafers have been under development. For example, a through silicon via (TSV) technique is a technique for connecting individual wafers by forming a trench penetrating a silicon substrate and forming a through via structure in the trench. For example, a through via structure (e.g., the first through via structure 50) may penetrate an upper substrate (e.g., the second substrate 200) to connect a wiring (e.g., the second wiring 212) in the upper substrate to a wiring (e.g., the first wiring 112) in a lower substrate (e.g., the first substrate 100).

In addition, to connect the through via structure to the wiring of the lower substrate, a trench exposing the wiring of the lower substrate may be formed. However, it may be difficult to control the depth of the trench exposing the wiring of the lower substrate due to a variation in an etching process. For example, the trench may selectively expose only a specific wiring (e.g., a landing wiring) connected to the through via structure, but a phenomenon that an inter-wiring insulating film is over-etched or under-etched may occur due to a variation in etching process. This may cause a poor contact of a through via trench, which may degrade product reliability.

However, in the semiconductor device according to an exemplary embodiment of the present inventive concept, since the first through via structure 50 is connected to the first landing via 190 formed by the via process, a contact failure of the first through via structure 50 may be prevented. For example, since the first landing via 190 may be formed with a finer pitch (e.g., DS2) than that of the wirings 112 and 112L formed by a wiring process, the first inter-wiring insulating film 110 may be prevented from being over-etched by the etching process for forming the through via trench 10t. In addition, as a result of this, a process margin of the etching process may be improved, so that the first inter-wiring insulating film 110 may be prevented in advance from being under-etched. Accordingly, the semiconductor device according to an exemplary embodiment of the present inventive concept may include the first landing via 190, thereby increasing product reliability.

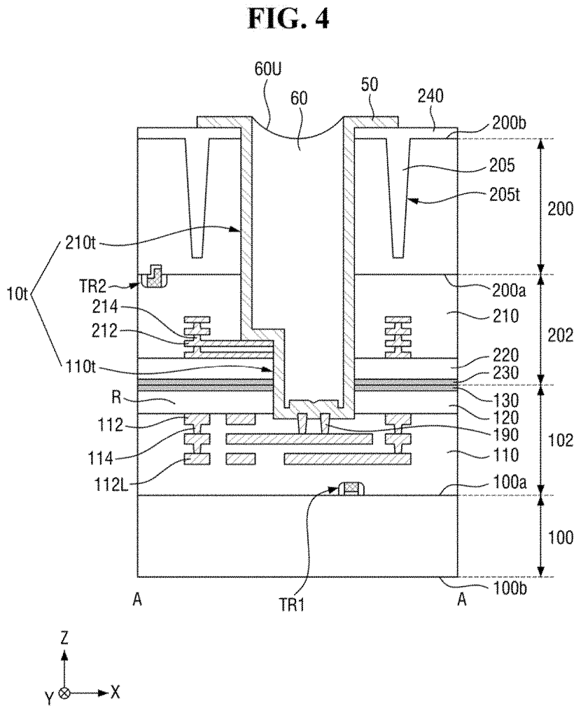

FIG. 4 is a schematic cross-sectional view illustrating a semiconductor device according to an exemplary embodiment of the present inventive concept. For simplicity of description, redundant parts of the description made with reference to FIGS. 1 to 3 may be recapitulated or omitted.

Referring to FIG. 4, in the semiconductor device according to an exemplary embodiment of the present inventive concept, the first landing via 190 is in contact with the lower wiring 112L.

For example, the lower wiring 112L may be formed to at least partially overlap the first landing via 190. Here, the term “overlap” means overlapping in a plan view (e.g., in the third direction Z). For example, the bottom surface of the first landing via 190 may contact the top surface of the lower wiring 112L.

Accordingly, the first landing via 190 may be electrically connected to a part of the plurality of wirings 112 and 112L. In addition, the first landing via 190 may electrically connect the first through via structure 50 to the plurality of wirings 112 and 112L.

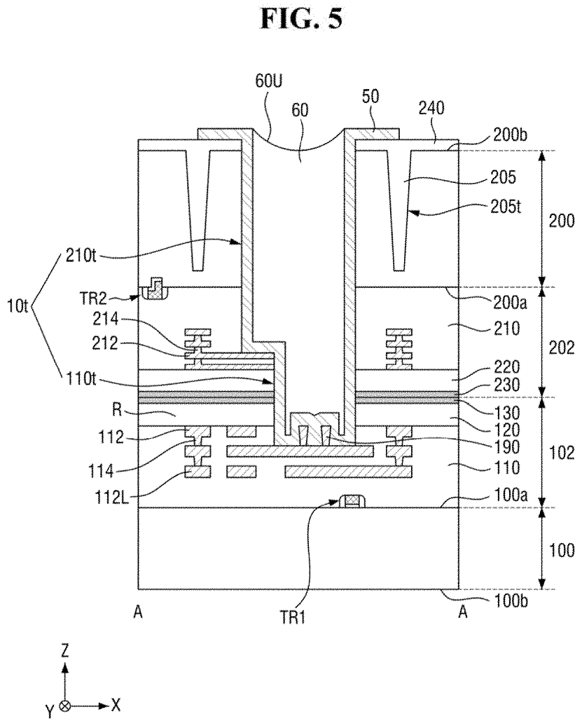

FIG. 5 is a schematic cross-sectional view illustrating a semiconductor device according to an exemplary embodiment of the present inventive concept. For simplicity of description, redundant parts of the description made with reference to FIGS. 1 to 4 may be recapitulated or omitted.

Referring to FIG. 5, in the semiconductor device according to an exemplary embodiment of the present inventive concept, the first through via structure 50 is in contact with the lower wiring 112L.

For example, the first sub-trench 110t may expose at least a part of the top surface of the lower wiring 112L. Accordingly, a part of the first through via structure 50 may extend along the top surface of the lower wiring 112L and the side surface of the first landing via 190. For example, the lower surface of the first through via structure 50 and the lower surface of the first landing via 190 may be coplanar.

The lower wiring 112L may function as an etch stop film to prevent the first inter-wiring insulating film 110 from being over-etched in the etching process of forming the through via trench 10t. Accordingly, the semiconductor device with increased product reliability may be provided.

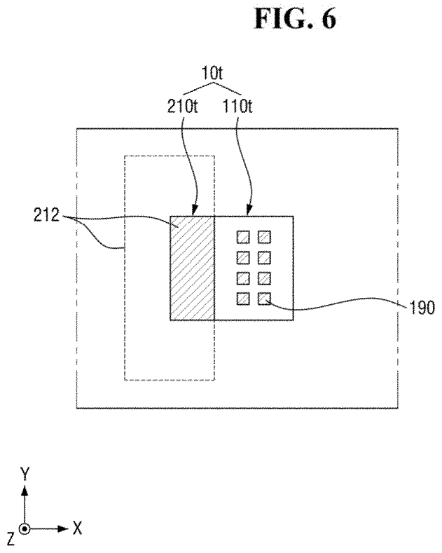

FIG. 6 is a diagram illustrating a semiconductor device according to an exemplary embodiment of the present inventive concept. For simplicity of description, redundant parts of the description made with reference to FIGS. 1 to 5 may be recapitulated or omitted.

Referring to FIG. 6, in the semiconductor device according to an exemplary embodiment of the present inventive concept, the first landing via 190 has a polygonal pillar shape.

For example, the first landing via 190 may have a rectangular pillar shape extending in the third direction Z. For example, the first landing via 190 may have a cuboid shape.

The first landing via 190 having the polygonal pillar shape may further reduce a pitch with adjacent first landing vias 190. Accordingly, the semiconductor device with increased product reliability may be provided.

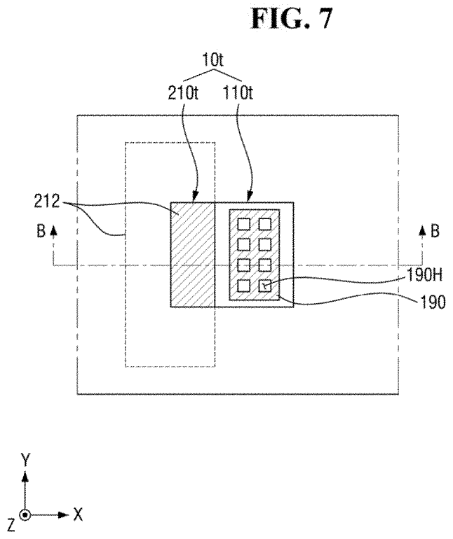

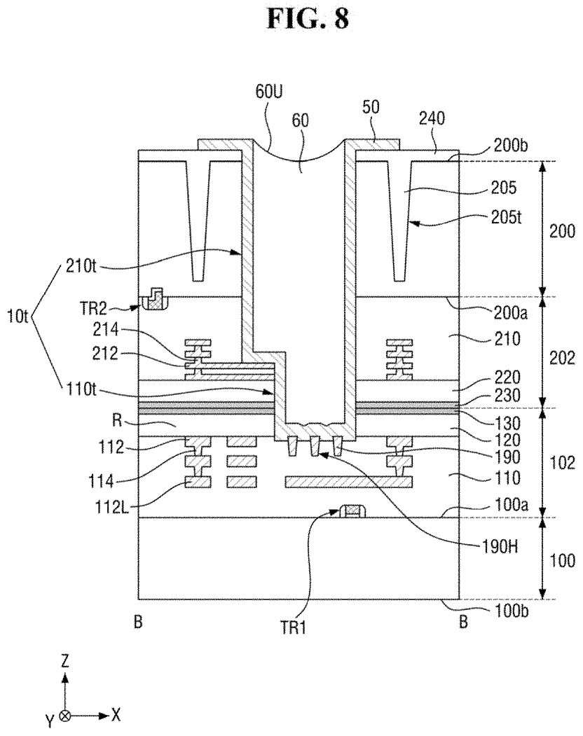

FIG. 7 is a diagram illustrating a semiconductor device according to an exemplary embodiment of the present inventive concept. FIG. 8 is a schematic cross-sectional view taken along line B-B of FIG. 7. For simplicity of description, redundant parts of the description made with reference to FIGS. 1 to 6 may be recapitulated or omitted.

Referring to FIGS. 7 and 8, in the semiconductor device according to an exemplary embodiment of the present inventive concept, the first landing via 190 includes a plurality of holes 190H.

For example, the first landing via 190 may be a plate-shaped structure extending on a plane including the first direction X and the second direction Y. As an additional example, the first landing via 190 may have a polygonal shape, such as a rectangular shape, or a circular shape. The plurality of holes 190H of the first landing via 190 may extend in the third direction Z to penetrate the first landing via 190. Each of the holes 190H is shown to have a rectangular pillar shape, but this is merely an example. For example, each of the holes 190H may have a cylindrical shape or other polygonal pillar shapes.

In an exemplary embodiment of the present inventive concept, each of the holes 190H may have a width that decreases as it goes away from the second surface 100a of the first substrate 100. For example, this may be due to the fact that an etching process for forming the first landing via 190 is performed toward the second surface 100a of the first substrate 100.

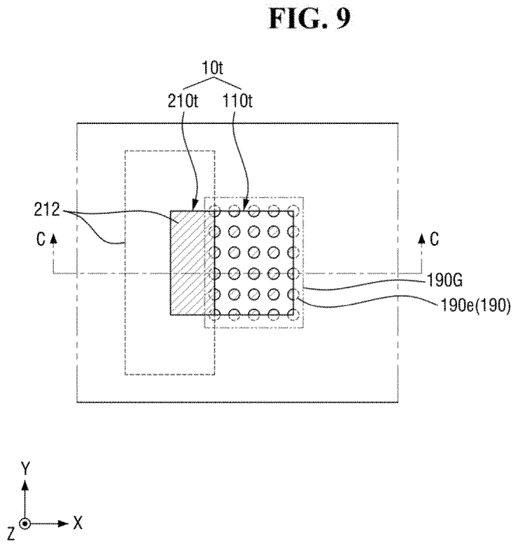

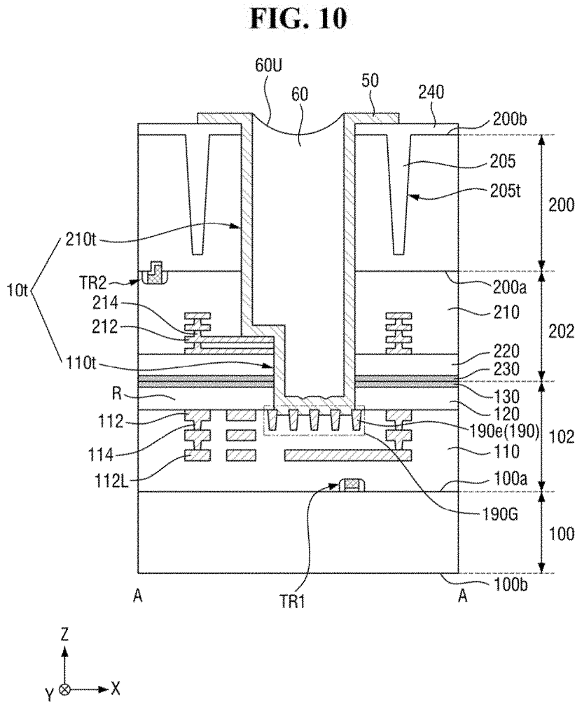

FIG. 9 is a layout diagram illustrating a semiconductor device according to an exemplary embodiment of the present inventive concept. FIG. 10 is a schematic cross-sectional view taken along line C-C of FIG. 9. For simplicity of description, redundant parts of the description made with reference to FIGS. 1 to 8 may be recapitulated or omitted.

Referring to FIGS. 9 and 10, in the semiconductor device according to an exemplary embodiment of the present inventive concept, at least a part of the first landing via 190 does not overlap the through via trench 10t.

For example, a part of the first landing via 190 may overlap the first sub-trench 110t in the third direction Z, and another part of the first landing via 190 may not overlap the first sub-trench 110t in the third direction Z.

A plurality of first landing vias 190 may be provided to form a landing via group 190G. The first landing vias 190 of the landing via group 190G may be arranged, for example, in a lattice shape on a plane including the first direction X and the second direction Y, but the present inventive concept is not limited thereto. The landing via group 190G may include edge landing vias 190e disposed at an edge thereof.

In an exemplary embodiment of the present inventive concept, at least a part of the edge landing vias 190e may not overlap with the first sub-trench 110t. For example, as illustrated in FIG. 9, the size of an area in which the landing via group 190G is formed may be larger than the size of an area in which the first sub-trench 110t is formed, in a plan view.

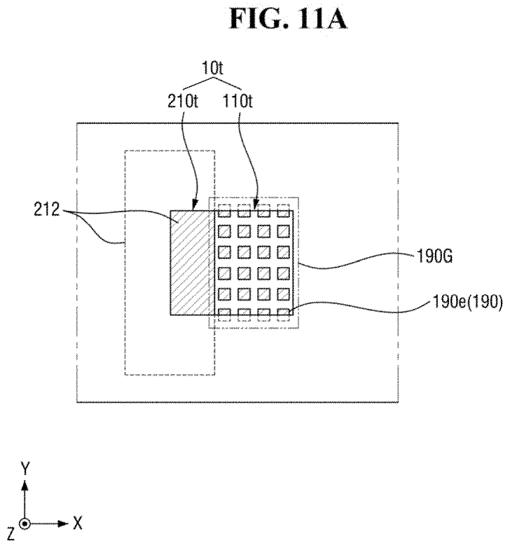

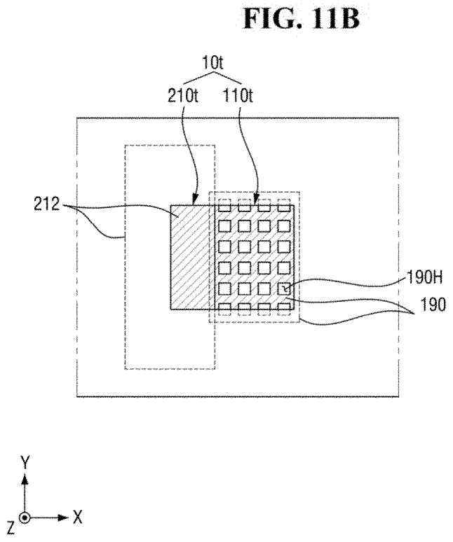

FIG. 11A is a layout diagram illustrating a semiconductor device according to an exemplary embodiment of the present inventive concept. For simplicity of description, redundant parts of the description made with reference to FIGS. 1 to 10 may be recapitulated or omitted.

Referring to FIG. 11A, in the semiconductor device according to an exemplary embodiment of the present inventive concept, the first landing via 190 has a polygonal pillar shape.

For example, the first landing via 190 may have a rectangular pillar shape extending in the third direction Z.

In an exemplary embodiment of the present inventive concept, at least a part of the first landing via 190 having a rectangular pillar shape may not overlap the through via trench 10t. For example, a part of the first landing via 190 having the rectangular pillar shape may overlap the first sub-trench 110t in the third direction Z, and the other part of the first landing via 190 having the rectangular pillar shape may not overlap the first sub-trench 110t in the third direction Z. For example, another first landing via 190 may be completely overlapped by the first sub-trench 110t.

In an exemplary embodiment of the present inventive concept, at least a part of the edge landing via 190e may not overlap the first sub-trench 110t. For example, in a plan view, the size of an area in which the landing via group 190G is formed may be larger than the size of an area in which the first sub-trench 110t is formed.

FIG. 11B is a diagram illustrating a semiconductor device according to an exemplary embodiment of the present inventive concept. For simplicity of description, redundant parts of the description made with reference to FIGS. 1 to 10 may be recapitulated or omitted.

Referring to FIG. 11B, in the semiconductor device according to an exemplary embodiment of the present inventive concept, the first landing via 190 includes the plurality of holes 190H.

In an exemplary embodiment of the present inventive concept, at least a part of the first landing via 190 does not overlap the through via trench 10t. For example, in a plan view, the size of an area in which the first landing via 190 is formed may be larger than the size of an area in which the first sub-trench 110t is formed.

In an exemplary embodiment of the present inventive concept, at least a part of a first group of holes 190H of the plurality of holes 190H of the first landing via 190 may not overlap the through via trench 10t. For example, a part of the first group of holes 190H of the plurality of holes 190H may overlap the first sub-trench 110t in the third direction Z, and the other part of the first group of holes 190H of the plurality of holes 190H may not overlap the first sub-trench 110t in the third direction Z.

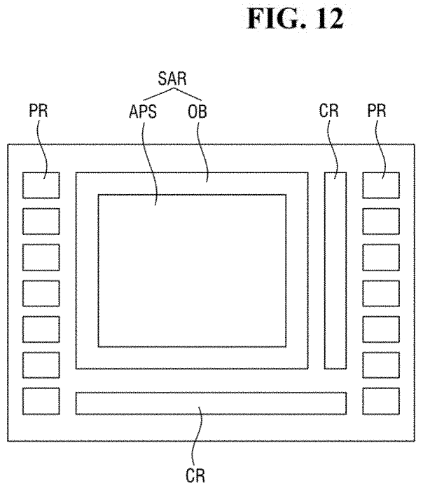

Hereinafter, an image sensor including the semiconductor device described above with reference to FIGS. 1 to 11B will be described with reference to FIGS. 12 to 14. In FIGS. 12 to 14, an image sensor is described as an example of the semiconductor device according to an exemplary embodiment of the present inventive concept, but the present inventive concept is not limited thereto. The semiconductor device according to an exemplary embodiment of the present inventive concept may be applied to other electronic sensors such as an iris sensor or a fingerprint recognition sensor, as well as other semiconductor devices in which individual wafers (e.g., lower and upper substrates) are stacked.

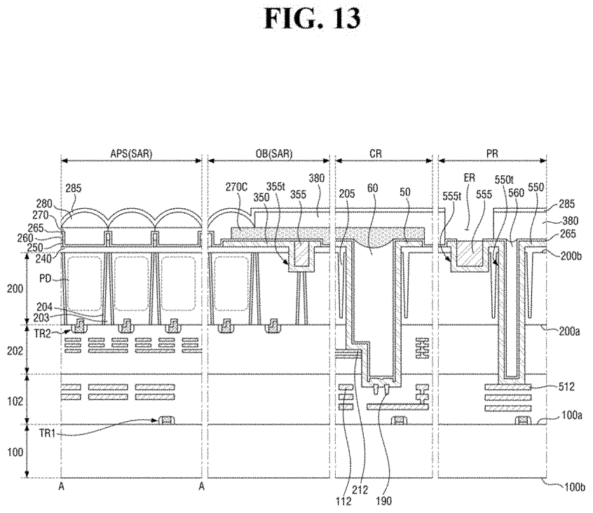

FIG. 12 is a layout diagram illustrating an image sensor according to an exemplary embodiment of the present inventive concept. FIG. 13 is a schematic cross-sectional view illustrating the image sensor of FIG. 12. For simplicity of description, redundant parts of the description made with reference to FIGS. 1 to 11B may be recapitulated or omitted.

Referring to FIGS. 12 and 13, the semiconductor device (hereinafter, image sensor) according to an exemplary embodiment of the present inventive concept includes a sensor array region SAR, a connection region CR, and a pad region PR.

A plurality of unit pixels arranged two-dimensionally (e.g., in a matrix form) may be formed in the sensor array region SAR. Each unit pixel in the sensor array region SAR may include a photoelectric conversion layer PD. The photoelectric conversion layer PD may be formed in the second substrate 200. The photoelectric conversion layer PD may generate electric charges in proportion to an amount of light incident from the outside. For example, the photoelectric conversion layer PD may be formed by doping impurities into the second substrate 200. For example, the photoelectric conversion layer PD may be formed by ion-implanting n-type impurities into the second substrate 200 which is of a p-type.

The photoelectric conversion layer PD may include, for example, at least one of a photodiode, a phototransistor, a photogate, a pinned photodiode, an organic photodiode, quantum dots, or a combination thereof, but the present inventive concept is not limited thereto.

In an exemplary embodiment of the present inventive concept, the unit pixels in the sensor array region SAR may be provided by a pixel isolation pattern 203 and 204 formed in the second substrate 200. The pixel isolation pattern 203 and 204 may be formed, for example, by filling an insulating material in a trench that has been formed by patterning the second substrate 200.

In an exemplary embodiment of the present inventive concept, the pixel isolation pattern 203 and 204 may include a spacer film 204 and a filling pattern 203. The spacer film 204 may conformally extend along the side surface of the trench in the second substrate 200. The filling pattern 203 may be formed on the spacer film 204 to fill at least a part of the trench in the second substrate 200.

In an exemplary embodiment of the present inventive concept, the spacer film 204 may include an oxide having a lower refractive index than that of the second substrate 200. For example, the spacer film 204 may include at least one of silicon oxide, aluminum oxide, tantalum oxide, or a combination thereof, but the present inventive concept is not limited thereto.

In an exemplary embodiment of the present inventive concept, the filling pattern 203 may include a conductive material. For example, the filling pattern 203 may include polysilicon, but the present inventive concept is not limited thereto. In an exemplary embodiment of the present inventive concept, a ground voltage or a negative voltage may be applied to the filling pattern 203 including the conductive material.

The sensor array region SAR may include a light receiving region APS and a light blocking region OB. Active pixels that receive light to generate active signals may be arranged in the light receiving region APS. Optical black pixels that generate optical black signals by blocking light may be arranged in the light blocking region OB. The light blocking region OB may, for example, at least partially surround the periphery of the light receiving region APS, but this is merely an example.

In an exemplary embodiment of the present inventive concept, the photoelectric conversion layer PD may not be formed in a part of the light blocking region OB. For example, the photoelectric conversion layer PD may be formed in the second substrate 200 in the light blocking region OB adjacent to the light receiving region APS, but may not be formed in the second substrate 200 in the light blocking region OB spaced apart from the light receiving region APS. As an additional example, the photoelectric conversion layer PD, in the light receiving region APS, may be disposed at a first side of the photoelectric conversion layer PD in the light blocking region OB, and a photoelectric conversion layer PD may not be disposed, in the light blocking region OB, at a second side of the photoelectric conversion layer PD of the light blocking region OB. Further, the second side of the photoelectric conversion layer PD of the light blocking region OB may be opposite to the first side thereof. In an exemplary embodiment of the present inventive concept, dummy pixels may be formed in the light receiving region APS adjacent to the light blocking region OB.

In an exemplary embodiment of the present inventive concept, the fourth surface 200b of the second substrate 200 may be a light receiving surface on which light is incident. For example, the image sensor according to an exemplary embodiment of the present inventive concept may be a backside illuminated (BSI) image sensor.

In an exemplary embodiment of the present inventive concept, the surface insulating film 240, color filters 270, and microlenses 280 may be formed on the second substrate 200 in the light receiving region APS.

The surface insulating film 240 may extend along the fourth surface 200b of the second substrate 200. The surface insulating film 240 may include, for example, at least one of silicon oxide, silicon nitride, silicon oxynitride, aluminum oxide, or hafnium oxide, but the present inventive concept is not limited thereto.

In an exemplary embodiment of the present inventive concept, the surface insulating film 240 may include multiple films. For example, the surface insulating film 240 may include an aluminum oxide film, a hafnium oxide film, a silicon oxide film, a silicon nitride film, and a hafnium oxide film that are sequentially stacked on the fourth surface 200b of the second substrate 200, but the present inventive concept is not limited thereto.

The surface insulating film 240 may function as an anti-reflection film to prevent reflection of light incident on the second substrate 200, thereby increasing a light receiving rate of the photoelectric conversion layer PD. For example, the surface insulating film 240 may function as a planarization layer to allow the color filters 270 and the microlenses 280, which will be described later, to be formed with a substantially uniform height.

The color filters 270 may be formed on the surface insulating film 240. The color filters 270 may be arranged to respectively correspond to the unit pixels of the sensor array region SAR.

The color filters 270 may have various color filters according to unit pixels PX1 to PX9. For example, the color filters 270 may be arranged in a Bayer pattern including a red filter, a green filter, and a blue filter. However, this is merely an example, and for example, the color filters 270 may include a yellow filter, a magenta filter, and a cyan filter, and may further include a white filter.

In an exemplary embodiment of the present inventive concept, a grid pattern 250 and 260 may be formed between the color filters 270. The grid pattern 250 and 260 may be formed on the surface insulating film 240. The grid pattern 250 and 260 may be interposed between the color filters 270. In an exemplary embodiment of the present inventive concept, the grid pattern 250 and 260 may be disposed to overlap the pixel isolation pattern 203 and 204 in a vertical direction (e.g., the third direction Z).

In an exemplary embodiment of the present inventive concept, the grid pattern 250 and 260 may include a conductive pattern 250 and a low refractive index pattern 260. The conductive pattern 250 and the low refractive index pattern 260 may, for example, be sequentially stacked on the surface insulating film 240.

The conductive pattern 250 may include, for example, at least one of titanium (Ti), titanium nitride (TiN), tantalum (Ta), tantalum nitride (TaN), tungsten (W), aluminum (Al), or copper (Cu), but the present inventive concept is not limited thereto.

In an exemplary embodiment of the present inventive concept, the conductive pattern 250 may be formed at the same level as the first through via structure 50. For example, the conductive pattern 250 and the first through via structure 50 may be disposed on the surface insulating film 240. The term “formed at the same level” as used herein means being formed by the same manufacturing process. For example, the conductive pattern 250 and the first through via structure 50 may be formed of the same conductive material.

The low refractive index pattern 260 may include a low refractive index material having a refractive index lower than that of silicon (Si). For example, the low refractive index pattern 260 may include at least one of silicon oxide, aluminum oxide, tantalum oxide, or a combination thereof, but the present inventive concept is not limited thereto. The low refractive index pattern 260 may refract or reflect light incident at an angle to increase light collection efficiency, thereby increasing the quality of the image sensor.

In an exemplary embodiment of the present inventive concept, the low refractive index pattern 260 may be formed at the same level as the filling insulating film 60. For example, the low refractive index pattern 260 and the filling insulating film 60 may be formed of the same insulating material.

In an exemplary embodiment of the present inventive concept, a first passivation film 265 may be formed on the surface insulating film 240 and the grid pattern 250 and 260. For example, the first passivation film 265 may conformally extend along the profiles of the top surface of the surface insulating film 240 and the side and top surfaces of the grid pattern 250 and 260.

The first passivation film 265 may include, for example, aluminum oxide, but the present inventive concept is not limited thereto. The first passivation film 265 may prevent damage to the surface insulating film 240 and the grid pattern 250 and 260.

The microlenses 280 may be formed on the color filters 270. The microlenses 280 may be arranged to respectively correspond to the unit pixels of the sensor array region SAR.

The microlens 280 has a convex shape and may have a predetermined radius of curvature. Accordingly, the microlens 280 may condense light incident on the photoelectric conversion layer PD. The microlens 280 may include, for example, a light transmitting resin, but the present inventive concept is not limited thereto.

In an exemplary embodiment of the present inventive concept, a second passivation film 285 may be formed on the microlenses 280. The second passivation film 285 may extend along the surfaces of the microlenses 280. The second passivation film 285 may include, for example, an inorganic oxide film (e.g., silicon oxide, titanium oxide, zirconium oxide, hafnium oxide, or a combination thereof), but the present inventive concept is not limited thereto. In an exemplary embodiment of the present inventive concept, the second passivation film 285 may include low temperature oxide (LTO).

The second passivation film 285 may protect the microlenses 280 from external conditions. For example, the second passivation film 285 may include the inorganic oxide film to protect the microlenses 280 including an organic material. In addition, the second passivation film 285 may increase the quality of the image sensor by increasing light collection efficiency of the microlenses 280. For example, the second passivation film 285 may fill a space between the microlenses 280, thereby reducing reflection, refraction, scattering, and the like of incident light reaching the space between the microlenses 280.

In an exemplary embodiment of the present inventive concept, a pad structure 350 may be formed in the light blocking region OB. The pad structure 350 may be formed on the surface insulating film 240 in the light blocking region OB. The pad structure 350 may overlap the pixel isolation pattern 203 and 204. For example, the pad structure 350 may contact the pixel isolation pattern 203 and 204.

For example, a first trench 355t exposing the pixel isolation pattern 203 and 204 may be formed in the second substrate 200 and the surface insulating film 240 in the light blocking region OB. The pad structure 350 may be formed in the first trench 355t to be brought into contact with the pixel isolation pattern 203 and 204 in the light blocking region OB. In an exemplary embodiment of the present inventive concept, the pad structure 350 may extend along the profile of the side and bottom surfaces of the first trench 355t.

The pad structure 350 may include, for example, at least one of titanium (Ti), titanium nitride (TiN), tantalum (Ta), tantalum nitride (TaN), tungsten (W), aluminum (Al), or copper (Cu), but the present inventive concept is not limited thereto. In an exemplary embodiment of the present inventive concept, the pad structure 350 may be formed at the same level as the first through via structure 50. For example, the pad structure 350 and the first through via structure 50 may be formed on the surface insulating film 240. For example, the pad structure 350 and the first through via structure 50 may be formed of the same conductive material.

In an exemplary embodiment of the present inventive concept, the pad structure 350 may be electrically connected to the pixel isolation pattern 203 and 204 to apply a ground voltage or a negative voltage to the pixel isolation pattern 203 and 204.

In an exemplary embodiment of the present inventive concept, a first pad 355 filling the first trench 355t may be formed on the pad structure 350. The first pad 355 may include, for example, at least one of tungsten (W), copper (Cu), aluminum (Al), gold (Au), silver (Ag), or an alloy thereof, but the present inventive concept is not limited thereto.

In an exemplary embodiment of the present inventive concept, the first passivation film 265 may cover the pad structure 350 and the first pad 355. For example, the first passivation film 265 may extend along the profiles of the pad structure 350 and the first pad 355.

The connection region CR may be formed around the sensor array region SAR. The connection region CR may be formed on at least one side of the sensor array region SAR, but the present inventive concept is merely an example. Wirings are formed in the connection region CR, and may be configured to transmit and receive electrical signals from the sensor array region SAR.

In an exemplary embodiment of the present inventive concept, the semiconductor device described above with reference to FIGS. 1 to 11B may be formed in the connection region CR. For example, the first wiring 112, the first landing via 190, the second wiring 212, and the first through via structure 50 may be formed in the connection region CR.

In an exemplary embodiment of the present inventive concept, the second wiring 212 may be electrically connected to the unit pixels of the sensor array region SAR. For example, the second electronic element TR2 on the second substrate 200 may be disposed to correspond to each unit pixel of the sensor array region SAR. The second wiring 212 may extend across the sensor array region SAR to the connection region CR to be connected to the second electronic element TR2. Accordingly, the second wiring 212 may be configured to transmit and receive electrical signals from the sensor array region SAR.

In an exemplary embodiment of the present inventive concept, the first electronic element TR1 on the first substrate 100 may be electrically connected to the sensor array region SAR. For example, the second wiring 212 may be electrically connected to the first landing via 190 through the first through via structure 50. In addition, the first landing via 190 may be electrically connected to a part (e.g., the first wiring 112) of the plurality of wirings in the first insulating structure 102. Accordingly, the first electronic element TR1 may transmit and receive electrical signals to and from each unit pixel of the sensor array region SAR.

The first electronic element TR1 may include, for example, at least one of a row decoder, a row driver, a column decoder, a timing generator, and a correlated double sampler (CDS), an analog-to-digital converter (ADC), or an I/O buffer, which constitutes the image sensor, but the present inventive concept is not limited thereto.

In an exemplary embodiment of the present inventive concept, the first passivation film 265 may cover the first through via structure 50. For example, the first passivation film 265 may be interposed between the first through via structure 50 and the filling insulating film 60.

The first passivation film 265 may conformally extend along the profile of the first through via structure 50.

The pad region PR may be formed around the sensor array region SAR. The pad region PR may be formed adjacent to the edge of the image sensor according to an exemplary embodiment of the present inventive concept, but this is merely an example. The pad region PR may be connected to an external device or the like to allow the image sensor according to an exemplary embodiment of the present inventive concept to transmit and receive electrical signals to and from the external device.

In FIG. 12, the connection region CR is shown to be interposed between the sensor array region SAR and the pad region PR, but this is merely an example. For example, the arrangement of the sensor array region SAR, the connection region CR, and the pad region PR may vary.

In an exemplary embodiment of the present inventive concept, a second through via structure 550 may be formed in the pad region PR. The second through via structure 550 may be formed on the surface insulating film 240 in the pad region PR. The second through via structure 550 may allow the image sensor according to an exemplary embodiment of the present inventive concept to be electrically connected to the external device or the like.

For example, a third wiring 512 may be formed in the first insulating structure 102 in the pad region PR. In addition, a second trench 550t exposing the third wiring 512 may be formed in the second substrate 200 and the surface insulating film 240 in the pad region PR. The second through via structure 550 may be formed in the second trench 550t to be brought into contact with the third wiring 512. In addition, a third trench 555t may be formed in the second substrate 200 in the pad region PR. The second through via structure 550 may be formed in the third trench 555t and may be exposed. In an exemplary embodiment of the present inventive concept, the second through via structure 550 may extend along the profiles of the side and bottom surfaces of the second trench 550t and the third trench 555t.

The second through via structure 550 may include, for example, at least one of titanium (Ti), titanium nitride (TiN), tantalum (Ta), tantalum nitride (TaN), tungsten (W), aluminum (Al), or copper (Cu), but the present inventive concept is not limited thereto. In an exemplary embodiment of the present inventive concept, the second through via structure 550 may be formed at the same level as the first through via structure 50. For example, the second through via structure 550 and the first through via structure 50 may be formed of the same conductive material.

In an exemplary embodiment of the present inventive concept, a second filling insulating film 560 that fills the second trench 550t may be formed on the second through via structure 550. The second filling insulating film 560 may include, for example, at least one of silicon oxide, aluminum oxide, tantalum oxide, or a combination thereof, but the present inventive concept is not limited thereto. In an exemplary embodiment of the present inventive concept, the second filling insulating film 560 may be formed at the same level as the filling insulating film 60. For example, the second filling insulating film 560 and the filling insulating film 60 may be formed of the same insulating material. However, the present inventive concept is not limited thereto.

In an exemplary embodiment of the present inventive concept, a second pad 555 that fills the third trench 555t may be formed on the second through via structure 550. The second pad 555 may include, for example, at least one of tungsten (W), copper (Cu), aluminum (Al), gold (Au), silver (Ag), or an alloy thereof, but the present inventive concept is not limited thereto. In an exemplary embodiment of the present inventive concept, the second pad 555 may be formed at the same level as the first pad 355.

In an exemplary embodiment of the present inventive concept, the first passivation film 265 may cover the second through via structure 550. For example, the first passivation film 265 may extend along the profile of the second through via structure 550. For example, the first passivation film 265 may cover an upper surface and side surfaces of the second through via structure 550. In an exemplary embodiment of the present inventive concept, the first passivation film 265 may expose the second pad 555.

In an exemplary embodiment of the present inventive concept, a light blocking color filter 270C may be formed above the pad structure 350 and the first through via structure 50. For example, the light blocking color filter 270C may be formed to cover a part of the first passivation film 265 in the light blocking region OB and the connection region CR. The light blocking color filter 270C may include, for example, a blue filter, but the present inventive concept is not limited thereto.

In an exemplary embodiment of the present inventive concept, a third passivation film 380 may be formed on the light blocking color filter 270C. For example, the third passivation film 380 may be formed to cover at least a part of the first passivation film 265 in the light blocking region OB, the connection region CR, and the pad region PR. In an exemplary embodiment of the present inventive concept, the second passivation film 285 may extend along the surface of the third passivation film 380. The third passivation film 380 may include, for example, a light transmitting resin, but the present inventive concept is not limited thereto. In an exemplary embodiment of the present inventive concept, the third passivation film 380 may include the same material as the microlens 280.

In an exemplary embodiment of the present inventive concept, the second passivation film 285 and the third passivation film 380 may expose the second pad 555. For example, an exposure opening ER that exposes the second pad 555 may be formed in the second passivation film 285 and the third passivation film 380. Accordingly, the second pad 555 may be connected to the external device or the like through the exposure opening ER to allow the image sensor according to an exemplary embodiment of the present inventive concept to transmit and receive electrical signals to and from the external device.

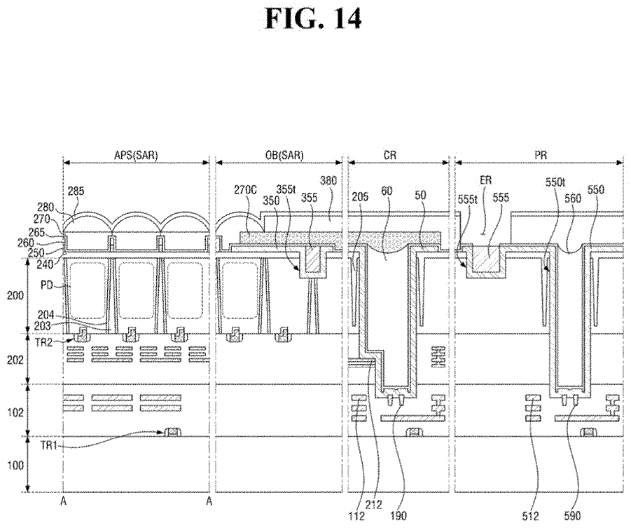

FIG. 14 is a schematic cross-sectional view illustrating an image sensor according to an exemplary embodiment of the present inventive concept. For simplicity of description, redundant parts of the description made with reference to FIGS. 1 to 13 may be recapitulated or omitted.

Referring to FIG. 14, in the image sensor according to an exemplary embodiment of the present inventive concept, the second through via structure 550 is electrically connected to a second landing via 590.

For example, the second landing via 590 may be formed in the first insulating structure 102 in the pad region PR. Since the second landing via 590 may be similar to the first landing via 190 except that it is formed in the pad region PR, a detailed description thereof will be omitted below.

The second pad 555 may be electrically connected to the second landing via 590 through the second through via structure 550. In addition, the second landing via 590 may be electrically connected to a part (e.g., the third wiring 512) of the plurality of wirings in the first insulating structure 102. Accordingly, the second pad 555 may be connected to the external device or the like to allow the image sensor according to an exemplary embodiment of the present inventive concept to transmit and receive electrical signals to and from the external device.

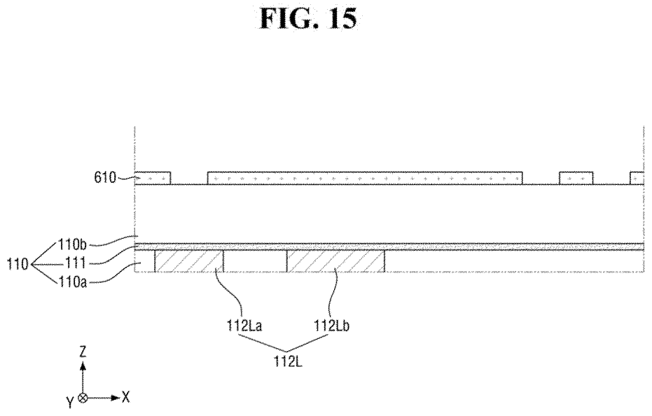

Hereinafter, a method for fabricating a semiconductor device according to an exemplary embodiment of the present inventive concept will be described with reference to FIGS. 1 to 22. For reference, FIGS. 15 to 22 are diagrams describing an area corresponding to area R of FIG. 2.

FIGS. 15 to 22 are views illustrating steps of a method for fabricating a semiconductor device according to an exemplary embodiment of the present inventive concept. For simplicity of description, redundant parts of the description made with reference to FIGS. 1 to 14 may be recapitulated or omitted.

Referring to FIG. 15, a first mask pattern 610 is formed on the first inter-wiring insulating film 110.

The first inter-wiring insulating film 110 may be formed of multiple films. For example, as illustrated in FIG. 3, the first inter-wiring insulating film 110 may include the lower insulating film 110a and the upper insulating film 110b which are sequentially stacked on the second surface 100a of the first substrate 100.

In an exemplary embodiment of the present inventive concept, the lower wiring 112L may be formed in the lower insulating film 110a. The lower wiring 112L may include, for example, the first lower wiring 112La and the second lower wiring 112Lb adjacent to each other.

In an exemplary embodiment of the present inventive concept, the etch stop film 111 may be interposed between the lower insulating film 110a and the upper insulating film 110b. For example, the etch stop film 111 may be formed to cover the top surface of the lower insulating film 110a.

The first mask pattern 610 may expose at least a part of the upper insulating film 110b. The first mask pattern 610 may include, for example, a photosensitive material (e.g., photoresist), but the present inventive concept is not limited thereto. In an exemplary embodiment of the present inventive concept, the first mask pattern 610 may expose a portion of the upper insulating film 110b overlapping the first lower wiring 112La.

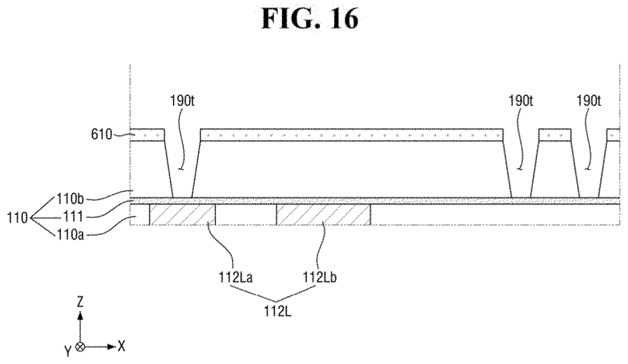

Referring to FIG. 16, the upper insulating film 110b is patterned using the first mask pattern 610 as an etching mask.

As the upper insulating film 110b is patterned, the second via trench 190t may be formed in the upper insulating film 110b. In an exemplary embodiment of the present inventive concept, the second via trench I 90t may expose the etch stop film 111. In an exemplary embodiment of the present inventive concept, the width of the second via trench 190t may decrease as it approaches the lower insulating film 110. In an exemplary embodiment of the present inventive concept, since at least a part of the first mask pattern 610 may expose a part of the upper insulating film 110b overlapping the first lower wiring 112La, at least a part of the second via trench 190t may be formed to overlap the first lower wiring 112La.

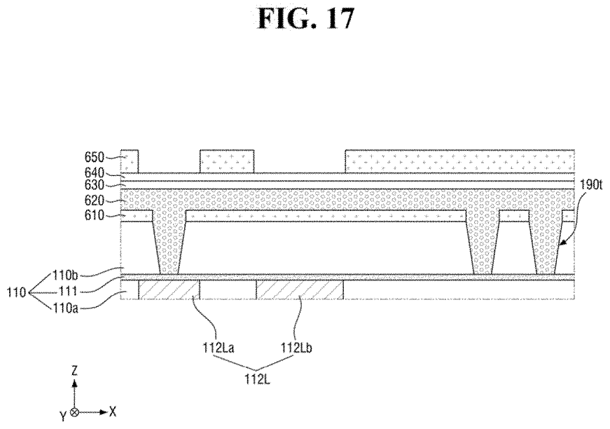

Referring to FIG. 17, a sacrificial film 620, a first hard mask film 630, a second hard mask film 640, and a second mask pattern 650 are sequentially formed on the upper insulating film 110b.

For example, the sacrificial film 620 may be formed on the first mask pattern 610. The sacrificial film 620 may be formed to fill the second via trench 190t in the upper insulating film 110b.

The first hard mask film 630, the second hard mask film 640, and the second mask pattern 650 may be sequentially formed on the sacrificial film 620. The second mask pattern 650 may include, for example, a photosensitive material (e.g., photoresist), but the present inventive concept is not limited thereto. In an exemplary embodiment of the present inventive concept, the second mask pattern 650 may expose portions of the second hard mask film 640 overlapping the first lower wiring 112La and/or the second lower wiring 112Lb.

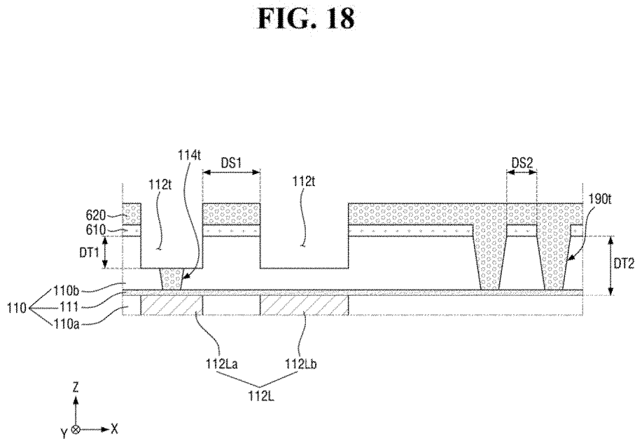

Referring to FIG. 18, the upper insulating film 110b is patterned using the second mask pattern 650 as an etching mask.

As the upper insulating film 110b is patterned, a wiring trench 112t may be formed in the upper insulating film 110b. In an exemplary embodiment of the present inventive concept, the bottom surface of the wiring trench 112t may be spaced apart from the top surface of the etch stop film 111. In an exemplary embodiment of the present inventive concept, since the second mask pattern 650 may expose portions of the upper insulating film 110b overlapping the first lower wiring 112La and/or the second lower wiring 112Lb, the wiring trench 112t may be formed to overlap the first lower wiring 112La and/or the second lower wiring 112Lb.

In addition, in an exemplary embodiment of the present inventive concept, the wiring trench 112t may be formed to overlap the second via trench 190t. Accordingly, a first via trench 114t extending from the bottom surface of the wiring trench 112t may be formed in the upper insulating film 110b.

As described above, the second via trench 190t may be formed by a via process, and the wiring trench 112t may be formed by a wiring process. Accordingly, the second via trench 190t may be formed with a finer pitch than that of the wiring trench 112t. For example, a separation distance DS2 between the second via trenches 190t may be smaller than a separation distance DS1 between the wiring trenches 112t.

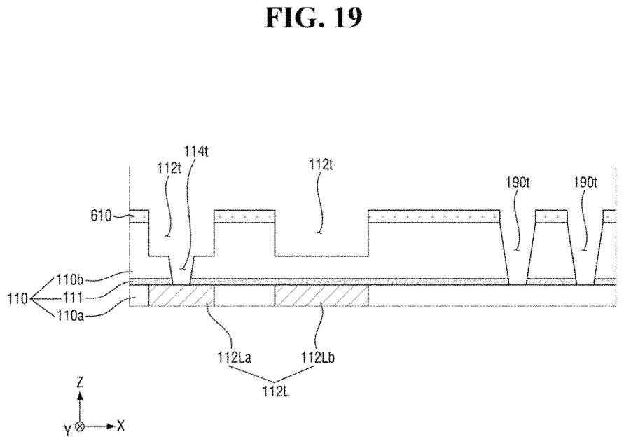

Referring to FIG. 19, the sacrificial film 620 is removed.

For example, the sacrificial film 620 in the first via trench 114t and the second via trench 190t may be removed. The removal of the sacrificial film 620 may be performed by, for example, an ashing process, but the present inventive concept is not limited thereto.

In an exemplary embodiment of the present inventive concept, after the sacrificial film 620 is removed, portions of the etch stop film 111 exposed by the first via trench 114t and the second via trench 190t may be removed. For example, the portions of the etch stop film 111 exposed by the first via trench 114t and the second via trench 190t may be, for example, removed together with the sacrificial film 620 by a process (e.g., an ashing process) of removing the sacrificial film 620, but the present inventive concept is not limited thereto. Accordingly, portions of the first lower wiring 112La and/or the lower insulating film 110a may be exposed by the first via trench 114t and the second via trench 190t, respectively.

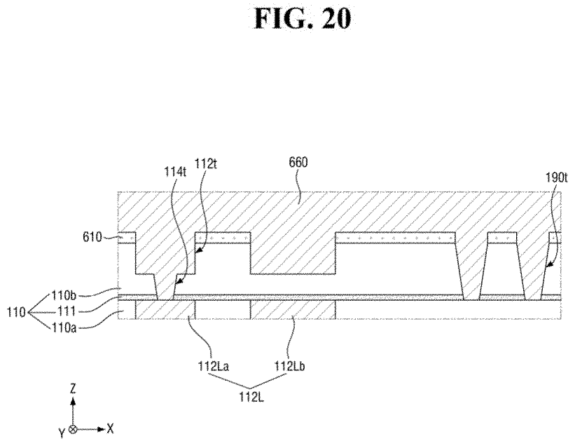

Referring to FIG. 20, a conductive film 660 is formed in the upper insulating film 110b.

For example, the conductive film 660 may be formed on the first mask pattern 610. The conductive film 660 may be formed to fill the first via trench 114t, the wiring trench 112t, and the second via trench 190t. Accordingly, the conductive film 660 may be connected to the portions of the first lower wiring 112La and/or the lower insulating film 110a exposed by the first via trench 114t and the second via trench 190t, respectively.

The conductive film 660 may include, for example, at least one of copper (Cu), tungsten (W), tungsten nitride (WN), tantalum (Ta), titanium (Ti), tantalum nitride (TaN), titanium nitride (TiN), cobalt (Co), manganese (Mn), aluminum (Al), or aluminum nitride (AlN), but the present inventive concept is not limited thereto.

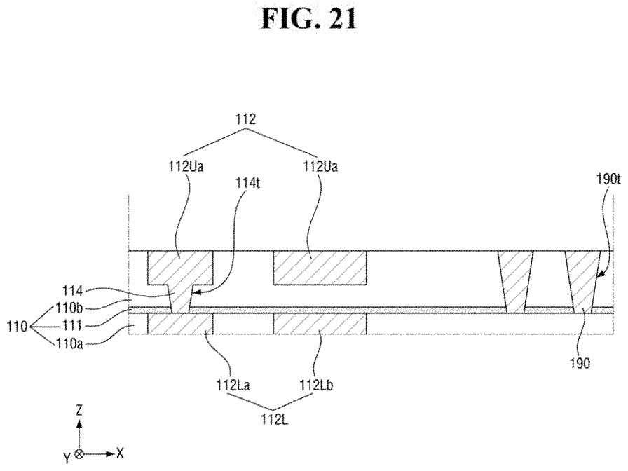

Referring to FIG. 21, a planarization process is performed on the conductive film 660.

For example, the planarization process may be performed on the conductive film 660 until the top surface of the upper insulating film 110b is exposed. The planarization process may include, for example, a chemical mechanical polishing (CMP) process, but the present inventive concept is not limited thereto.

Accordingly, the first connection via 114 filling the first via trench 114t, the first wiring 112 filling the wiring trench 112t, and the first landing via 190 filling the second via trench 190t may be formed.

In an exemplary embodiment of the present inventive concept, the first connection via 114 may extend from the first upper wiring 112Ua to connect the first upper wiring 112Ua to the first lower wiring 112La. For example, the first connection via 114 may extend from the bottom surface of the first upper wiring 112Ua.

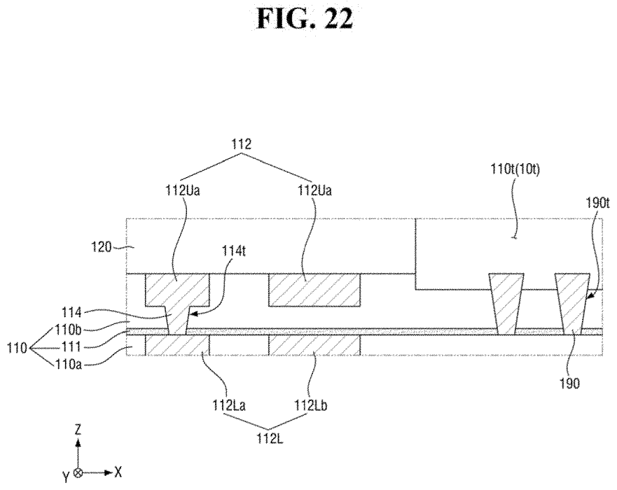

Referring to FIG. 22, the through via trench 10t exposing the first landing via 190 is formed.

For example, the first interlayer insulating film 120 may be formed to cover the upper insulating film 110b. For example, the first interlayer insulating film 120 may cover the top surface of the upper insulating film 110b. Subsequently, the through via trench 10t exposing the first landing via 190 may be formed in the first interlayer insulating film 120. In an exemplary embodiment of the present inventive concept, the bottom surface of the through via trench 10t may be formed at the same level as or below the top surface of the first landing via 190.

Next, referring to FIGS. 1 to 3, the first through via structure 50 filling the through via trench 10t is formed.

Accordingly, the first through via structure 50 selectively connected to the first landing via 190 may be formed. In an exemplary embodiment of the present inventive concept, the first through via structure 50 may conformally extend along the profile of the through via trench 10t.

Accordingly, the method for fabricating the semiconductor device with increased product reliability may be provided.

While the present inventive concept has been described with reference to exemplary embodiments thereof, it will be understood by those of ordinary skill in the art that various changes in form and details may be made thereto without departing from the spirit and scope of the present inventive concept as defined by the following claims.

What is claimed is:

1. A semiconductor device comprising:
a first substrate including a first surface and a second surface opposite to each other;
a first inter-wiring insulating film stacked on the first substrate;
a first wiring in the first inter-wiring insulating film;
a landing via in the first inter-wiring insulating film, wherein the landing via is spaced apart from the first wiring;
a second substrate overlapping the first substrate and including a third surface and a fourth surface opposite to the third surface;
a second inter-wiring insulating film stacked on the second substrate;
a second wiring in the second inter-wiring insulating film; and
a through via structure configured to penetrate the second substrate and the second inter-wiring insulating film, and to electrically connect the second wiring to the landing via,
wherein with respect to the second surface of the first substrate, a top surface of the landing via is higher than a bottom surface of the first wiring, and a bottom surface of the landing via is lower than the bottom surface of the first wiring.

2. The semiconductor device of claim 1, further comprising a through via trench extending from the fourth surface of the second substrate, and exposing at least a part of the second wiring and at least a part of the landing via, and
wherein the through via structure extends along the through via trench.

3. The semiconductor device of claim 2, wherein at least a part of the landing via does not overlap the through via trench.

4. The semiconductor device of claim 2, further comprising a filling insulating film on the through via structure, wherein the filling insulating film fills the through via trench.

5. The semiconductor device of claim 4, wherein a top surface of the filling insulating film is concave.

6. The semiconductor device of claim 4, wherein the filling insulating film includes a low refractive index material having a refractive index lower than that of silicon (Si).

7. The semiconductor device of claim 1, wherein the top surface of the landing via is coplanar with a top surface of the first wiring.

8. The semiconductor device of claim 1, wherein the first wiring is an upper wiring among a plurality of wirings in the first inter-wiring insulating film.

9. The semiconductor device of claim 1, further comprising a connection via in the first inter-wiring insulating film, wherein the connection via extends from the first wiring, and
wherein the bottom surface of the landing via is coplanar with a bottom surface of the connection via.

10. The semiconductor device of claim 1, further comprising a lower wiring in the first inter-wiring insulating film, and
herein the bottom surface of the landing via is connected to a top surface of the lower wiring.

11. The semiconductor device of claim 10, wherein the through via structure extends along the top surface of the lower wiring and a side surface of the landing via.

12. The semiconductor device of claim 1, wherein a width of the landing via decreases as it approaches the second surface of the first substrate.

13. A semiconductor device comprising:
a first substrate including a first surface and a second surface opposite to each other;
a lower insulating film and an upper insulating film on the first substrate;
a lower wiring in the lower insulating film, wherein the lower wiring is exposed at a top surface of the lower insulating film;
a first wiring in the upper insulating film;
a connection via in the upper insulating film, wherein the connection via extends from the first wiring to connect the first wiring to the lower wiring;
a landing via in the upper insulating film, wherein the landing via is spaced apart from the first wiring;
a second substrate overlapping the first substrate and including a third surface and a fourth surface opposite to the third surface;
a second inter-wiring insulating film stacked on the second substrate; and
a through via structure configured to penetrate the second substrate and the second inter-wiring insulating film, and connected to the landing via,
wherein a top surface of the landing via is further spaced apart from the lower insulating film than a bottom surface of the first wiring, and
wherein a bottom surface of the landing via is coplanar with a bottom surface of the connection via.

14. The semiconductor device of claim 13, wherein the first wiring includes a first upper wiring and a second upper wiring adjacent to each other,
wherein the landing via includes a first landing via and a second landing via adjacent to each other, and
wherein a separation distance between the first landing via and the second landing via is smaller than a separation distance between the first upper wiring and the second upper wiring.

15. The semiconductor device of claim 13, wherein the landing via is formed in plural to from a landing via group.

16. The semiconductor device of claim 13, wherein the landing via includes a plurality of holes.

17. The semiconductor device of claim 13, wherein an acute angle formed by the top surface of the lower insulating film and a side surface of the landing via is the same as an acute angle formed by a top surface of the lower wiring and a side surface of the connection via.

18. A semiconductor device comprising:
a sensor array region;
a connection region around the sensor array region;
a first substrate including a first surface and a second surface opposite to each other;
a photoelectric conversion layer in the first substrate of the sensor array region;
a first insulating structure stacked on the first substrate;
a first wiring in the first insulating structure of the connection region;
a landing via in the first insulating structure of the connection region, wherein the landing via is spaced apart from the first wiring;
a second substrate overlapping the first substrate and including a third surface and a fourth surface opposite to the third surface;
a second insulating structure on the second substrate, wherein the second insulating structure is bonded to the first insulating structure; and
a through via structure configured to penetrate the second substrate and the second insulating structure, and connected to the landing via,
wherein with respect to the second surface of the first substrate, a top surface of the landing via is higher than a bottom surface of the first wiring, and a bottom surface of the landing via is lower than the bottom surface of the first wiring.

19. The semiconductor device of claim 18, wherein the first insulating structure includes a first adhesive film adjacent to the second insulating structure,
wherein the second insulating structure includes a second adhesive film bonded to the first adhesive film, and
wherein each of the first adhesive film and the second adhesive film includes silicon carbonitride (SiCN).

20. The semiconductor device of claim 18, further comprising:
an element isolation trench in the second substrate at a side of the through via structure, wherein the element isolation trench extends from the fourth surface of the second substrate; and
an element isolation pattern filling the element isolation trench.
